(19) United States
(12) Patent Application Publication
(10) Pub. No.: US 2025/0005235 A1
(43) Pub. Date: Jan. 2, 2025

(54) INTEGRATED AUTONOMOUS VEHICLE SIGNAL QUALITY-BASED REVIEW RECOMMENDATION SYSTEM

(71) Applicant: GM CRUISE HOLDINGS LLC, San Francisco, CA (US)

(72) Inventors: Jing Lu, San Francisco, CA (US); Kevin Li, Boston, MA (US); Tai Stillwater-Moon, San Francisco, CA (US); Riccardo Pavesi, San Francisco, CA (US); Shuaili Li, Fremont, CA (US)

(73) Assignee: GM CRUISE HOLDINGS LLC, SAN FRANCISCO, CA (US)

(21) Appl. No.: 18/342,788

(22) Filed: Jun. 28, 2023

(51) Int. Cl. G06F 30/27; G07C 5/08

(52) U.S. Cl. CPC G06F 30/27; G07C 5/0808

(57) ABSTRACT

Disclosed are embodiments for facilitating an integrated autonomous vehicle signal quality-based review recommendation system. In some aspects, an embodiment includes receiving performance results corresponding to tests performed using simulated mileage accumulation of at least one simulated autonomous vehicles (AV); filtering the tests based on validity information of the tests, wherein the tests that are identified as invalid are discarded; filtering the performance results of the tests identified as valid based on performance criteria to provide a set of selected tests; performing a sensitivity analysis on the set of selected tests to determine a trustworthiness signal for each selected test in the set of selected tests; and ranking and recommending one or more of the selected tests in the set of selected tests using a centralized ranking technique that considers the performance results and the trustworthiness signal of the selected tests.

### BACKGROUND

### 1. Technical Field

The disclosure generally relates to the field of processing systems and, more specifically, to an integrated autonomous vehicle signal quality-based review recommendation system.

### 2. Introduction

Autonomous vehicles, also known as self-driving cars, driverless vehicles, and robotic vehicles, may be vehicles that use multiple sensors to sense the environment and move without a human driver. An example autonomous vehicle can include various sensors, such as a camera sensor, a light detection and ranging (LIDAR) sensor, and a radio detection and ranging (RADAR) sensor, amongst others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system.

### BRIEF DESCRIPTION OF THE DRAWINGS

The various advantages and features of the disclosed technology will become apparent by reference to specific embodiments illustrated in the appended drawings. A person of ordinary skill in the art will understand that these drawings show some examples of the disclosed technology and would not limit the scope of the disclosed technology to these examples. Furthermore, the skilled artisan will appreciate the principles of the disclosed technology as described and explained with additional specificity and detail through the use of the accompanying drawings in which:

FIG. 1 is a block diagram of an example system 100 providing integrated autonomous vehicle (AV) signal quality-based review recommendations, in accordance with embodiments herein;

FIG. 2 is a block diagram of a detailed view of an example simulation platform providing for integrated AV signal quality-based review recommendations, in accordance with embodiments herein;

FIG. 3 illustrates a schematic depicting an integrated signal quality-based test review recommendation process performed by an integrated signal quality-based test review recommendation system, in accordance with embodiments herein;

FIG. 4 illustrates an example method implementing integrated AV signal quality-based review recommendations, in accordance with embodiments herein;

FIG. 5 illustrates an example method for implementing filtering as part of integrated AV signal quality-based review recommendations, in accordance with embodiments herein;

FIG. 6 illustrates an example method for implementing a sensitivity analysis as part of integrated AV signal quality-based review recommendations, in accordance with embodiments herein;

FIG. 7 illustrates an example system environment that can be used to facilitate AV dispatch and operations, according to some aspects of the disclosed technology;

FIG. 8 illustrates an example of a deep learning neural network that can be used to implement a perception module and/or one or more validation modules, according to some aspects of the disclosed technology; and

FIG. 9 illustrates an example processor-based system with which some aspects of the subject technology can be implemented.

### DETAILED DESCRIPTION

The detailed description set forth below is intended as a description of various configurations of the subject technology and is not intended to represent the configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

Autonomous vehicles (AVs), also known as self-driving cars, driverless vehicles, and robotic vehicles, can be implemented by companies to provide self-driving car services for the public, such as taxi or ride-hailing (e.g., ridesharing) services. The AV can navigate about roadways without a human driver based upon sensor signals output by sensor systems deployed on the AV. AVs may utilize multiple sensors to sense the environment and move without a human driver. An example AV can include various sensors, such as a camera sensor, a light detection and ranging (LIDAR) sensor, and a radio detection and ranging (RADAR) sensor, amongst others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system.

AVs can utilize one or more trained machine learning (ML)-based models for various purposes. One use of ML-based models is to autonomously control and/or operate the vehicle. The trained model(s) can utilize the data and measurements captured by the sensors of the AV to identify, classify, and/or track objects (e.g., vehicles, people, stationary objects, structures, animals, etc.) within the AV's environment. The model(s) utilized by the AV may be trained using any of various suitable types of learning, such as deep learning (also known as deep structured learning). Deep learning is part of a broader family of machine learning methods based on artificial neural networks with representation learning. The learning can be supervised, semi-supervised, or unsupervised, and may be trained using real-world image data and/or image data generated in a simulated environment that have been labeled according to “correct” outputs of one or more perception functions (e.g., segmentation, classification, and/or tracking) of the AV.

Performance of the trained ML-based models may be evaluated by simulating the AV ML-based models using various different simulated scenarios. A scenario may refer to one or more elements of an environment in which the AV operates, such as road/intersection type, time, weather, road participants, and so on. Advancements in graphics and simulation technology have increased the use of simulated data for training and validating machine learning models, especially for tasks where real world data is costly or impossible to acquire. In particular, training visual detection and understanding algorithms on synthetic (simulated or sim) image data can produce immense gains for a robotic system.

With respect to the use of simulated data for training an AV, simulated mileage accumulation may be employed to collect data to improve the AVs' algorithm training capability, sensor accuracy, and road data quality. Simulated mileage accumulation may refer to virtual simulation of the AV software in order to project AV performance in a variety of distinct scenarios. For example, the simulated mileage accumulation can replicate a variety of driving environments and/or reproduce real-world scenarios from data captured by previous on-road operation of one or more AVs, including rendering geospatial information and road infrastructure (e.g., streets, lanes, crosswalks, traffic lights, stop signs, etc.); modeling the behavior of other vehicles, bicycles, pedestrians, and other dynamic elements; simulating inclement weather conditions, different traffic scenarios; and so on.

Simulated mileage accumulation may implement various testing strategies to monitor and evaluate the performance of AVs. These testing strategies may be provided via testing suites, which can range in the size of 200K tests or greater in some cases. As such, there can be too many tests for AV engineers to review and distill in order to understand the performance of the AV. Moreover, this test review task can become even more difficult when simulation fidelity is not precise and/or there are multiple different scores reflecting on a single aspect of the tests. Furthermore, the test review task can be complicated by different use guidance being provided for each test.

In order to save time and cost for users, such as AV engineers, to review signals on AV test performance, embodiments herein provide an integrated AV signal quality-based review recommendation system. Embodiments herein aim to consider all available information related to a test scenario in order to sort and filter for the most representative and reliable signals for a user, such as an AV engineer, to review and iterate upon, for example, before releasing the AV code for on-road testing. Although the discussion herein may refer to AV engineers as the primary user that reviews signals and/or results generate by embodiments of the disclosure, other types of users may also utilize the integrated AV signal quality-based review recommendation system described herein. For case of discussion, AV engineers are discussed herein as the user of embodiments of the disclosure.

The integrated AV signal quality-based review recommendation system of embodiments herein includes a test review recommendation system that performs an integrated ranking process that utilizes test filtering based on test validity, test filtering based on performance qualifications, test sensitivity, and representativeness of individual tests. The test review recommendation system of embodiments herein implements a centralized ranking algorithm that considers, for each test performed by a simulated mileage accumulator, static test inputs, dynamic test inputs, historical test results, and current test results to produce a ranked list of test scenarios and their corresponding test results. The centralized ranking algorithm of the test review recommendation system determines the priority of the test scenarios for the ranking by considering test validity, performance qualifications, test sensitivity, and scene representation. The test review recommendation system provides representative tests that maximize information content for review by, for example, an AV engineer. This can remove the burden on the AV engineer to have to understand the varieties of test scores and also allow the AV engineer to locate useful information in a large test suite having complicated compositions and signals.

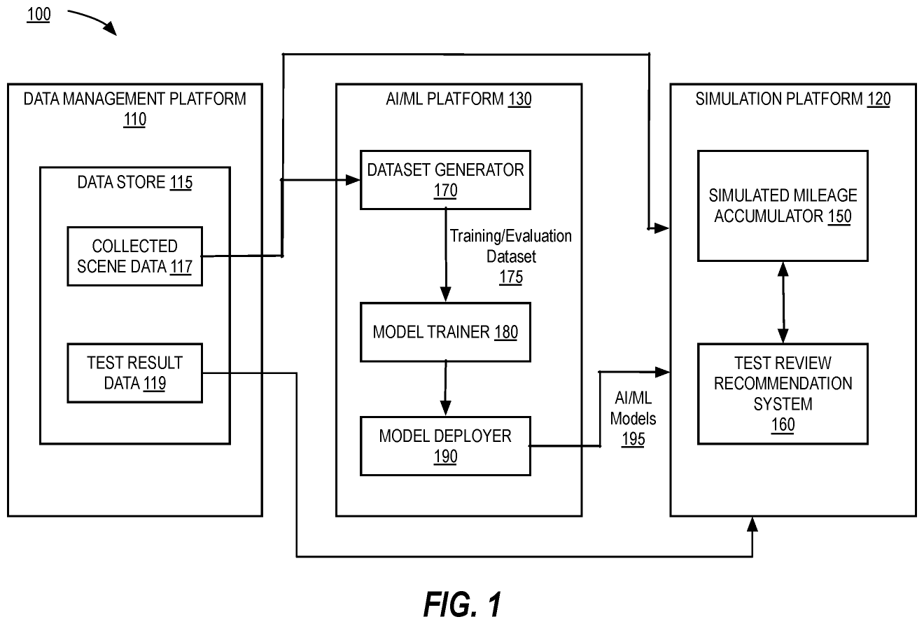

Although some embodiments herein are described as operating in an AV, other embodiments may be implemented in an environment that is not an AV, such as, for example, other types of vehicles (human operated, driver-assisted vehicles, etc.), air and terrestrial traffic control, radar astronomy, air-defense systems, anti-missile systems, marine radars to locate landmarks and other ships, aircraft anti-collision systems, ocean surveillance systems, outer space surveillance and rendezvous systems, meteorological precipitation monitoring, altimetry and flight control systems, guided missile target locating systems, ground-penetrating radar for geological observations, and so on. Furthermore, other embodiments may be more generally implemented in any artificial intelligence and/or machine learning-type environment. The following description discussed embodiments as implemented in an automotive environment, but one skilled in the art will appreciate that embodiments may be implemented in a variety of different environments and use cases. Further details of the integrated AV signal quality-based review recommendation system of embodiments herein are further described below with respect to FIGS. 1-9.

FIG. 1 is a block diagram of an example system 100 providing integrated AV signal quality-based review recommendations, in accordance with embodiments herein. In one embodiment, system 100 implements a simulation platform for providing an integrated AV signal quality-based review recommendation system, as described further herein. The system 100 of FIG. 1 can be, for example, part of a data center that is cloud-based or otherwise. In other examples, the system 100 can be part of an AV or a human-operated vehicle having an advanced driver assistance system (ADAS) that can utilize various sensors including radar sensors.

In one embodiment, system 100 can communicate over one or more networks (not shown), such as a public network (e.g., the Internet, an Infrastructure as a Service (IaaS) network, a Platform as a Service (PaaS) network, a Software as a Service (SaaS) network, another Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.). In one embodiment, system 100 can be implemented using a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and so forth.

The system 100 may be part of a data center for managing a fleet of AVs and AV-related services. The data center can send and receive various signals to and from an AV. These signals can include sensor data captured by the sensor systems of the AV, roadside assistance requests, software updates, ridesharing pick-up and drop-off instructions, and so forth. In some examples, the system 100 may be hosted in a data center that may also support a ridesharing service, a delivery service, a remote/roadside assistance service, street services (e.g., street mapping, street patrol, street cleaning, street metering, parking reservation, etc.), and the like. In some embodiments, the system 100 may be implemented in the AV itself or may be implemented in a server computing device.

In this example, the system 100 includes one or more of a data management platform 110, a simulation platform 120, and an Artificial Intelligence/Machine Learning (AI/ML) platform 130, among other systems.

Data management platform 110 can be a “big data” system capable of receiving and transmitting data at high speeds (e.g., near real-time or real-time), processing a large variety of data, and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service data, map data, audio data, video data, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. In one embodiment, the data management platform includes a data store 115 that stores scene data 117 collected, for example, from operation of one or more AVs. In some embodiments, scene data 117 may be training data provided from any source.

The simulation platform 120 can enable testing and validation of the algorithms, machine learning models, neural networks, and other development efforts for the AV, among other platforms and systems. The simulation platform 120 can replicate a variety of driving environments and/or reproduce real-world scenarios from data captured by the AV, including rendering geospatial information and road infrastructure (e.g., streets, lanes, crosswalks, traffic lights, stop signs, etc.); modeling the behavior of other vehicles, bicycles, pedestrians, and other dynamic elements; simulating inclement weather conditions, different traffic scenarios; and so on.

The AI/ML platform 130 can provide an infrastructure for training and evaluating machine learning algorithms for operating the AV, the simulation platform 120, and other platforms and systems. In one embodiment, the AI/ML platform 130 of system 100 may include a dataset generator 170, model trainer 180, and/or a model deployer 190. Using the dataset generator 170, model trainer 180, and/or the model deployer 190, data scientists can prepare data sets from the data management platform 110; select, design, and train machine learning models 195; evaluate, refine, and deploy the models 195; maintain, monitor, and retrain the models 195; and so on. For example, a training/evaluation dataset 175 generated by dataset generator 170 from collected scene data 117 can be used by model trainer 180 to train and/or evaluate an AI/ML model 195 that is to be deployed by model deployer 190. In one embodiment, model deployer 190 can deploy the AI/ML model 195 to simulation platform 120 for use as part of a simulated mileage accumulator 150.

In some embodiments, the simulation platform 120 is utilized to evaluate performance metrics (e.g., safety risks, etc.) of simulated AVs implementing AI/ML models 195 in simulated scenarios. In embodiments herein, the simulation platform 120 can include a simulated mileage accumulator 150 and test review recommendation system 160 to enable the integrated AV signal quality-based review recommendation system discussed herein. In some embodiments, the simulated mileage accumulator 150 may implement various testing strategies to monitor and evaluate the performance of AVs. These testing strategies may be provided via testing suites, which can range in the size of 200K tests or greater in some cases. As a result, there may be too many tests for AV engineers to review and distill in order to understand the performance of the AV. Moreover, this test review task can become even more difficult when simulation fidelity is not precise and/or there are multiple different scores reflecting on a single aspect of the tests. Furthermore, the test review task can be complicated by different use guidance being provided for cach test.

In order to save time and cost for the AV engineers to review signals on AV test performance (which may be stored as test result data 119 in data store 115), the simulation platform 120 may implement a test review recommendation system 160 to provide integrated AV signal quality-based test review recommendations. The test review recommendation system 160 can consider all available information related to a test scenario in order to sort and filter for the most representative and reliable signals (e.g., test results generated using the test scenario) for AV engineers to review and iterate upon, for example, before releasing the AV code for on-road testing.

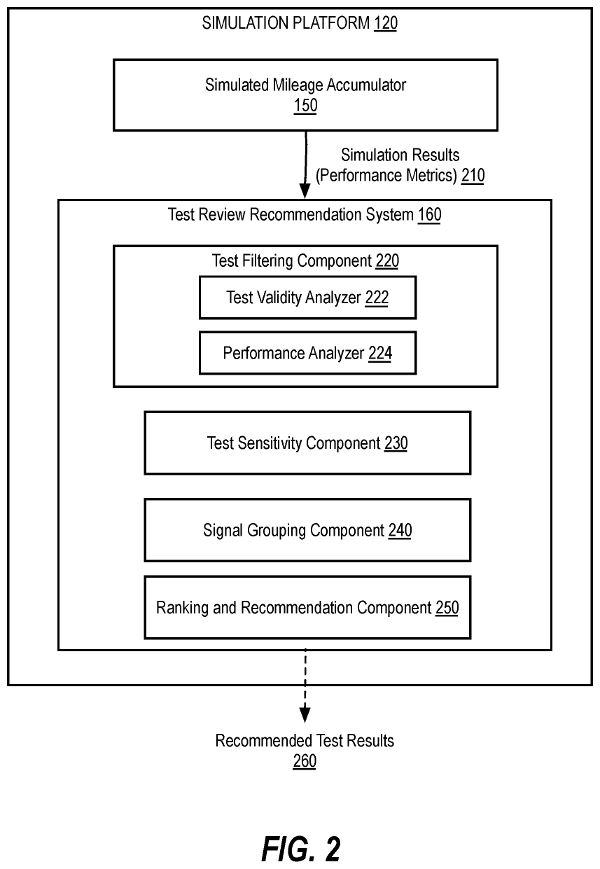

In one embodiment, the test review recommendation system 160 can perform an integrated ranking process that accounts for test filtering based on test validity, test filtering based on performance qualifications, test sensitivity, and representativeness of individual tests. The test review recommendation system 160 can implement a centralized ranking algorithm that considers, for each test performed by a simulated mileage accumulator, static test inputs, dynamic test inputs, historical test results, and/or current test results to produce a ranked list of test scenarios and their corresponding test results. The centralized ranking algorithm of the test review recommendation system 160 determines the priority of the test scenarios for the ranking by considering test validity, performance qualifications, test sensitivity, and scene representation. The test review recommendation system 160 provides representative tests (and test results) that maximize information content for review by an AV engineer. This can remove the burden on the AV engineer to have to understand all varieties of test scores and also allow the AV engineer to locate useful information in a large test suite having complicated compositions and signals. Further details of the integrated AV signal quality-based review recommendation system described here provided below with respect to FIG. 2.

FIG. 2 is a block diagram of a detailed view of an example simulation platform, such as simulation platform 120 of FIG. 1, providing for integrated AV signal quality-based review recommendations, in accordance with embodiments herein. In one embodiment, simulation platform 120 of FIG. 2 is the same as simulation platform 120 described with respect to FIG. 1.

In one embodiment, simulation platform 120 includes simulated mileage accumulator 150 and test review recommendation system 160, which may be the same as their identically-named counterparts described with respect to FIG. 1. As previously noted, the simulation platform 120 is utilized to evaluate performance metrics (e.g., safety risks, comfort scores, etc.) of simulated AVs implementing AI/ML models in simulated scenarios.

In embodiments herein, the simulation platform 120 can include a simulated mileage accumulator 150 and a test review recommendation system 160 to enable the integrated AV signal quality-based test review recommendations discussed herein. The simulated mileage accumulator 150 can simulate AV operation in order to collect data for model training and performance validation. Simulated mileage accumulator 150 may be employed to collect data to improve the AV's algorithm training capability, sensor accuracy, and road data quality. Simulated mileage accumulator 150 may provide virtual simulation of the AV software in order to project AV performance in a variety of distinct scenarios. Simulation results 210, including test results such as performance metrics (e.g., safety, comfort, etc.), can be outputted by simulated mileage accumulator 150 in response to running one or more tests using the virtual simulation of the AV software. In one embodiment, the performance metrics of simulation results 210 may include, but are not limited to, safety critical events (SCEs), miles per SCE, vehicle retrieval events (VREs), miles per VREs, remote assistance events, miles per remote assistance event, comfort scores, and so on.

The test review recommendation system 160 of embodiments herein can analyze the simulation results 210 to identify representative tests as recommended test results 260 that maximize information content for review by, for example, an AV engineer. In one embodiment, the test review recommendation system 160 may include a test filtering component 220, a test sensitivity component 230, a signal grouping component 240, and a ranking and recommendation component 250. The components 220-250 of test review recommendation system 160 can perform an integrated ranking process that accounts for test filtering based on test validity, test filtering based on performance qualifications, test sensitivity, and representativeness of individual tests.

The test filtering component 220 of test review recommendation system 160 may filter simulation results 210 utilizing test validity analyzer 222 and performance analyzer 224. Test validity analyzer 222 can provide a validity indication for the tests by detecting certain conditions of the tests including, but not limited to detections of hot start issues, road participant realism issues, divergence issues, and so on. In one embodiment, test runs with certain objective validity information detected, such as hot start and divergence issues, may be considered invalid without further analysis. Hot start issues and divergence issues occur when a simulated AV stack is sourced from data from an on-road real AV stack. A hot start issue refers to warming up the software stack nodes of the AV stack in order to properly start a reaction to the simulated environment. During the phase when the AV stack is initialized and integrating with a simulation. there may be incongruities of AV behavior from the AV stack that occur as compared the on-road version of the AV stack. These incongruities are referred to as hot start issues. Divergence issues refer to a divergence of the simulated AV from the real AV. In this case, as the sensor data for the simulated AV stack is sourced from the on-road AV stack, the simulated AV data can no longer be relied upon because it is so far diverged from the original source sensor data.

Test runs with subjective validity information detected, such as road participant realism (i.e., lack of road participant reactivity), may still be considered valid based on a context of the validity information. Road participant realism refers to whether road participants in the simulation (other than the AV) react sufficiently and quickly to the AV. In one embodiment, whether a non-vehicle road participants, such as a pedestrian road participant or a bike road participant, reacts sufficiently and quickly to the AV are less of a concern as compared to other vehicle road participant reactions. This is because the AV should be proactively cautious around non-vehicle road participants on the road regardless of the non-vehicle road participant's attention level. Such a context assessment may be performed by the test validity analyzer 222 for subjective validity assessments of tests when determining whether a test is considered valid or invalid.

In one embodiment, all tests flagged as valid by validity analyzer 222 may be passed to performance analyzer 224 for additional filtering. However, in some embodiments, test validity analyzer 222 and performance analyzer 224 may operate independently of one another.

In one embodiment, the performance analyzer 224 can reduce the number of test scenarios based on determined performance qualifications to apply to the test scenarios. In the test scenarios run by simulated mileage accumulator 150, there may be multiple performance metrics 210 generated that qualify an AV's performance, such as safety metrics, comfort metrics, collision severity scores, and so on. The performance analyzer 224 may provide a filtering mechanism that reduces the number of test scenarios based on determined performance qualification objectives. For example, the AV engineer may indicate a particular objective of surfacing test signals for safety that the AV engineer seeks to review. A filtering methodology can be applied by the performance analyzer 224 to identify the highest severity or safety critical events in the simulation results 210 (or of the valid tests of the simulation results 210 as filtered by test validity analyzer 222).

In another example, if the AV engineer indicates an objective of utilizing the simulation results 210 to understand comfort levels, then the performance analyzer 224 may identify simulation results 210 (e.g., valid simulation results) that are associated with occurrence of the least comfortable events.

In one embodiment, the performance analyzer 224 may apply weights to the test scores of the simulation results to identify those test results having the requested objective of the AV engineer. The performance analyzer 224 may also apply a determined thresholding (e.g., top X number of tests, top X % of tests, etc.) to the test results to reduce the number of test results returned.

In embodiments herein, the performance analyzer 224 may utilize information provided by the originator (e.g., creator, score owner, etc.) of a particular test to apply the performance qualification filtering. For example, the information may include a recommended score threshold of score usage (e.g., comparison-wise or absolute-wise) as well as other development information regarding the particular test. As a result, the performance analyzer 224 removes the dependencies and requirements of AV engineers to understand the performance of multiple test scores developed by different teams to quantify the performance of an AV and how to use them in practice.

The filtered test results are then passed as a set of selected tests to the test sensitivity component 230. The test sensitivity component 230 may perform a sensitivity analysis on the set of selected tests to determine a trustworthiness signal for each selected test. This trustworthiness signal may provide insight into how the test scenario may perform more broadly at its current fixed evaluation window (and/or latency configurations) and its sensitivity to noise. As such, this can provide the test scenario's “trustworthiness” to give actual signals. In one embodiments, an actual signal may refer to an accurate or reliable test result that is not sensitive to change or noise generated by the test scenario.

In one embodiment, the sensitivity analysis by test sensitivity component 230 may include performing test scenario perturbation across its evaluation window (and/or latency configurations). Test scenario perturbation includes examining the historical run of the test scenario and how sensitive the test scores of the test scenario is to the fixed configuration of the scenario and/or to slight changes in the scenario. For example, the test sensitivity component 230 may access historical test results to scan over a sweep of evaluation windows. Varying the evaluation start time (and therefore the moment at which the simulated AV is allowed to diverge from the road) may result in perturbed initial conditions for a replay execution, and therefore allows for exploring a neighborhood of the scenario tested by the initial replay test. The test results can then be analyzed together to provide a richer signal than the individual test scores. If the sensitivity analysis performed by the test sensitivity component 230 determines that a particular test result is sensitive to change and/or noisy, then a lower trustworthiness signal (e.g., less trustworthy) may be assigned to the test result. This provides an ability to downweigh the test suites that are sensitive and prone to noise.

In some embodiments, the signal grouping component 240 may perform unsupervised grouping on the set of selected tests outputted by the test filtering component 220 and their occurrence frequencies. This grouping can be performed in order to recommend more representative signals from the suite of tests. In one embodiment, the signal grouping component 240 may utilize static test inputs (such as road geometry) and dynamic test inputs (such as road participant intent and AV motion planning behavior/aggressiveness) to perform the unsupervised grouping into representative scenes referred to as signal groups. Examples of grouping may include, but are not limited to, maneuvers that the AV is making (e.g., unprotected left turn, lane change, going straight, etc.), type of vehicle interacting with, type of non-vehicle interacting with, and so on. In some embodiments, the signal grouping component 240 can utilize a scenario tag or other scenario taxonomy, as well as the static and dynamic test inputs, to enable the grouping of selected tests. In some embodiments, the signal groups may be utilized to identify representative test results from each signal group to the AV engineer. In other embodiments, the unsupervised grouping of the selected tests is an optional process.

The ranking and recommendation component 250 may utilize a centralized ranking algorithm to determine the priority of the test scenarios for ranking by considering the test validity, the performance qualifications, the test sensitivity, and the scene representation as provided by components 220-240. In some embodiments, the ranking and recommendation component 250 may apply the centralized ranking algorithm to utilize the signal groupings from unsupervised grouping at signal grouping component 240 to rank and recommend representatives from each signal group for AV engineers to review.

As a result, a set of recommended test results 260 are generated by the test review recommendation system 160 from the simulation results 210. The test review recommendation system 160 provides more representative tests by identifying a portfolio of tests that maximizes information content. This can free users, such as AV engineers, from having to understand each of the individual test scores and how to use them to find useful information in a large test suite with complicated compositions and signals.

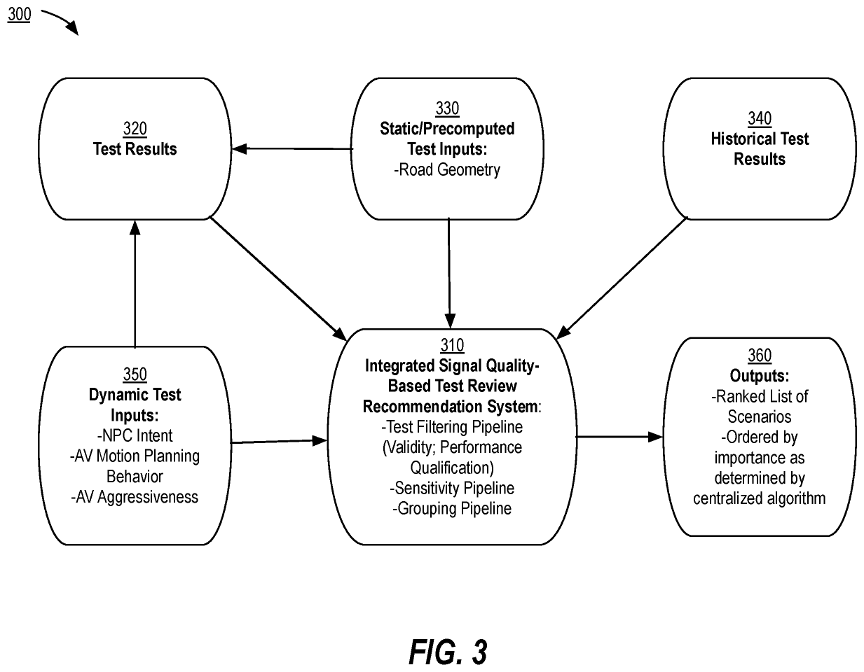

FIG. 3 illustrates a schematic 300 depicting an integrated signal quality-based test review recommendation process performed by integrated signal quality-based test review recommendation system 310, such as test review recommendation system 160 of FIGS. 1-2, in accordance with embodiments herein. The schematic 300 includes an integrated signal quality-based test review recommendation system 310 that may be the same as test review recommendation system 160 of FIGS. 1 and 2. Schematic 300 illustrates the integrated signal quality-based test review recommendation system 310 implementing a centralized ranking algorithm and the dependencies therein.

In one embodiment, the integrated signal quality-based test review recommendation system 310 considers, for each test performed by a simulated mileage accumulator, information generated by a test filtering pipeline, a sensitivity pipeline, and a grouping pipeline. In one embodiment, the centralized ranking algorithm of the integrated signal quality-based test review recommendation system 310 determines the priority of the test scenarios for the ranking by considering test validity, performance qualifications, test sensitivity, and scene representation. The various pipelines (test filtering, sensitivity, grouping) consider static (e.g., precomputed) test inputs 330, dynamic test inputs 350, historical test results 340, and/or current test results 320 to produce an output 360. The output 360 may include a ranked list of test scenarios and their corresponding test results. In one embodiment, the output 360 may be ordered by importance as determined by the centralized ranking algorithm.

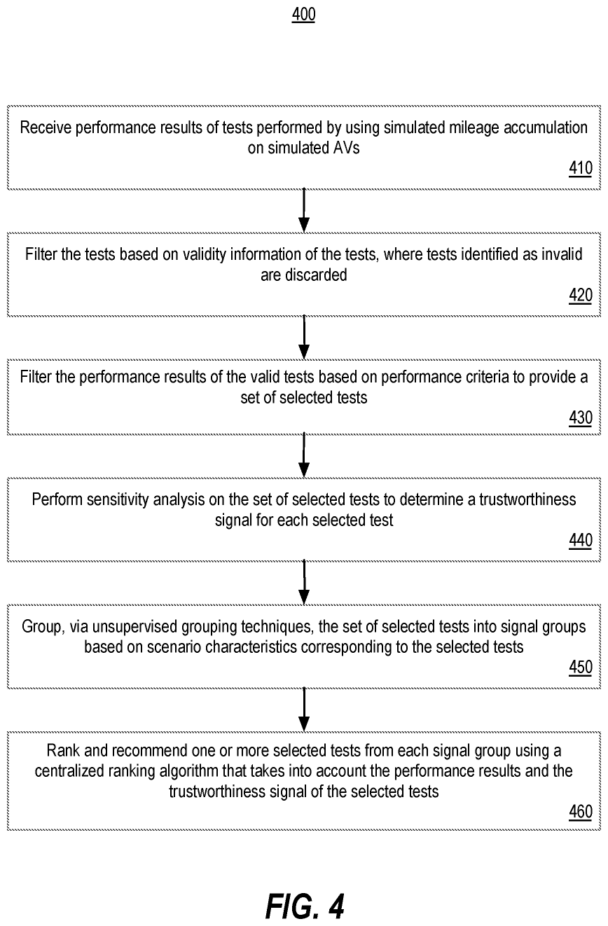

FIG. 4 illustrates an example method 400 implementing integrated AV signal quality-based review recommendations, in accordance with embodiments herein. Although the example method 400 depicts a particular sequence of operations, the sequence may be altered without departing from the scope of the disclosure. For example, some of the operations depicted may be performed in parallel or in a different sequence that does not materially affect the function of the method 400. In other examples, different components of an example device or system that implements the method 400 may perform functions at substantially the same time or in a specific sequence.

According to some embodiments, the method 400 includes block 410 where performance results are received of tests performed using simulated mileage accumulation on simulated AVs. Then, at block 420, the tests are filtered based on validity information of the tests, where tests identified as invalid are discarded. At block 430, the performance results of the valid tests are filtered based on performance criteria to provide a set of selected tests.

Subsequently, at block 440, a sensitivity analysis is performed on the set of selected tests to determine a trustworthiness signal for each selected test. Then, at block 450, the set of selected tests are grouped, using unsupervised grouping techniques, into signal groups based on scenario characteristics corresponding to the selected tests. Lastly, at block 460, one or more selected tests from each signal group are ranked and recommended using a centralized ranking algorithm that considers the performance results and the trustworthiness signal of the selected tests.

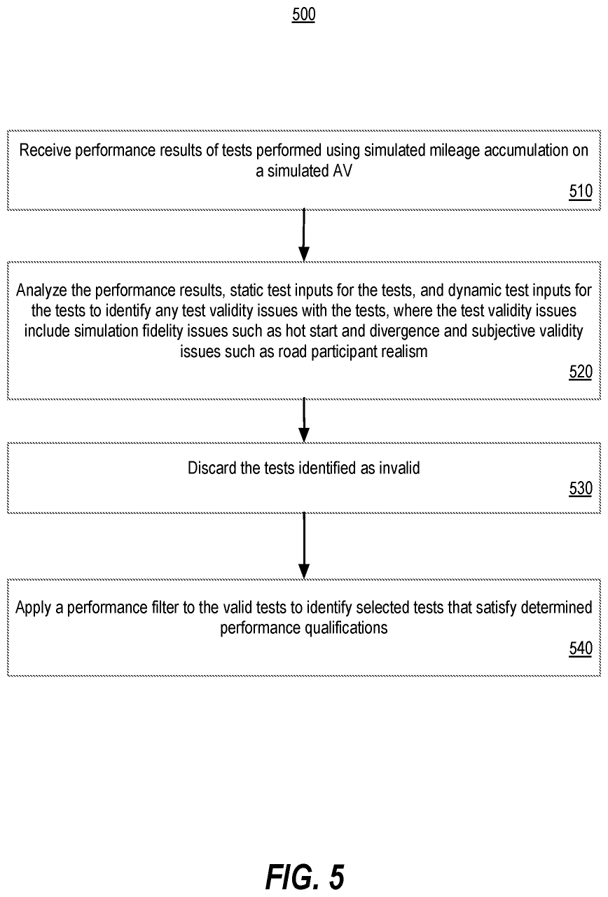

FIG. 5 illustrates an example method 500 for implementing filtering as part of integrated AV signal quality-based review recommendations, in accordance with embodiments herein. Although the example method 500 depicts a particular sequence of operations, the sequence may be altered without departing from the scope of the disclosure. For example, some of the operations depicted may be performed in parallel or in a different sequence that does not materially affect the function of the method 500. In other examples, different components of an example device or system that implements the method 500 may perform functions at substantially the same time or in a specific sequence.

According to some embodiments, the method 500 includes block 510 where performance results of tests performed using simulated mileage accumulation on a simulated AV are received. Then, at block 520, the performance results, static test inputs for the tests, and dynamic test inputs for the tests are analyzed to identify any test validity issues with the tests. In one embodiment, the test validity issues can include simulation fidelity issues (such as hot start and divergence (and can include subjective validity issues (such as road participant realism).

Subsequently, at block 530, the tests identified as invalid are discarded. Lastly, at block 540, a performance filter is applied to the valid tests to identify selected tests that satisfy determined performance qualifications.

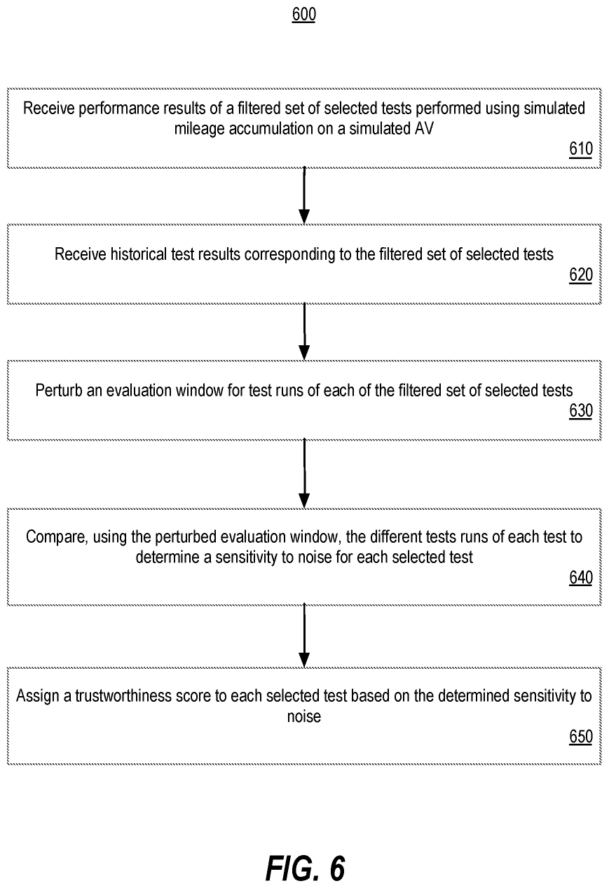

FIG. 6 illustrates an example method 600 for implementing a sensitivity analysis as part of integrated AV signal quality-based review recommendations, in accordance with embodiments herein. Although the example method 600 depicts a particular sequence of operations, the sequence may be altered without departing from the scope of the disclosure. For example, some of the operations depicted may be performed in parallel or in a different sequence that does not materially affect the function of the method 600. In other examples, different components of an example device or system that implements the method 600 may perform functions at substantially the same time or in a specific sequence.

According to some embodiments, the method 600 includes block 610 where performance results of a filtered set of selected tests performed using simulated mileage accumulation on a simulated AV are received. Then, at block 620, historical test results corresponding to the filtered set of selected tests are received.

Subsequently, at block 630, an evaluation window is perturbed for test runs of each of the filtered set of selected tests. At block 640, the different test runs of each test are compared, using the perturbed evaluation window, to determine a sensitivity to noise for each selected test. Lastly, at block 650, a trustworthiness score is assigned to each selected test based on the determined sensitivity to noise.

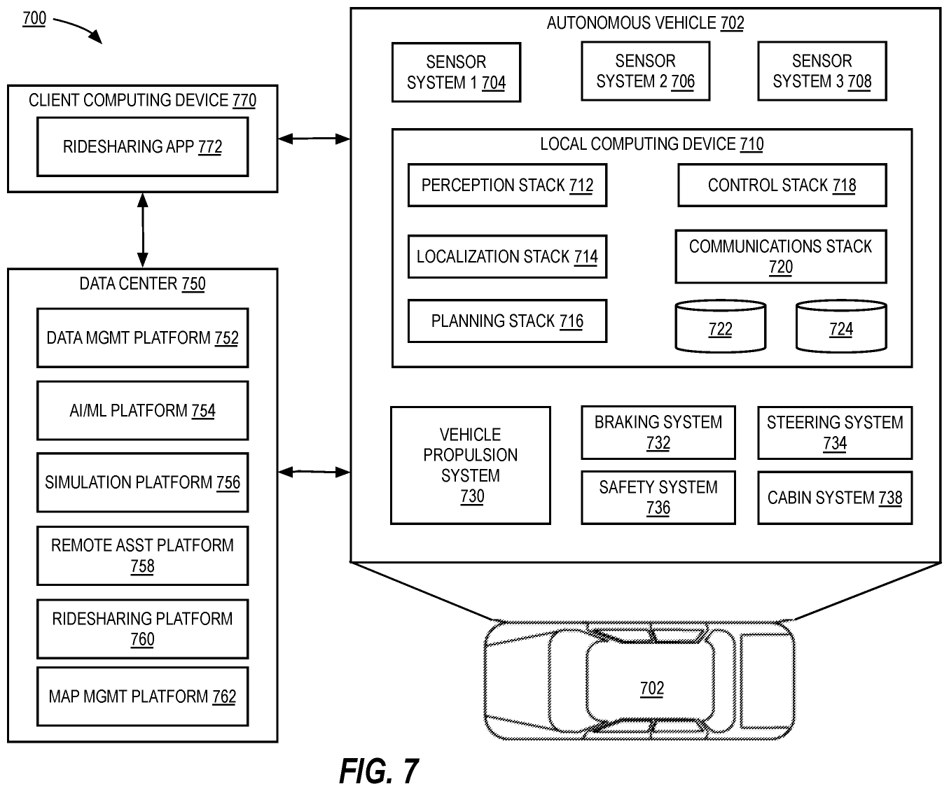

Turning now to FIG. 7, this figure illustrates an example of an AV management system 700. In one embodiment, the AV management system 700 can implement an integrated AV signal quality-based review recommendation system, as described further herein. One of ordinary skill in the art will understand that, for the AV management system 700 and any system discussed in the present disclosure, there can be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 700 includes an AV 702, a data center 750, and a client computing device 770. The AV 702, the data center 750, and the client computing device 770 can communicate with one another over one or more networks (not shown), such as a public network (e.g., the Internet, an Infrastructure as a Service (IaaS) network, a Platform as a Service (PaaS) network, a Software as a Service (SaaS) network, another Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 702 can navigate about roadways without a human driver based on sensor signals generated by multiple sensor systems 704, 706, and 708. The sensor systems 704-708 can include different types of sensors and can be arranged about the AV 702. For instance, the sensor systems 704-708 can comprise Inertial Measurement Units (IMUs), cameras (e.g., still image cameras, video cameras, etc.), light sensors (e.g., LIDAR systems, ambient light sensors, infrared sensors, etc.), RADAR systems, a Global Navigation Satellite System (GNSS) receiver, (e.g., Global Positioning System (GPS) receivers), audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 704 can be a camera system, the sensor system 706 can be a LIDAR system, and the sensor system 708 can be a RADAR system. Other embodiments may include any other number and type of sensors.

AV 702 can also include several mechanical systems that can be used to maneuver or operate AV 702. For instance, the mechanical systems can include vehicle propulsion system 730, braking system 732, steering system 734, safety system 736, and cabin system 738, among other systems. Vehicle propulsion system 730 can include an electric motor, an internal combustion engine, or both. The braking system 732 can include an engine brake, a wheel braking system (e.g., a disc braking system that utilizes brake pads), hydraulics, actuators, and/or any other suitable componentry configured to assist in decelerating AV 702. The steering system 734 can include suitable componentry configured to control the direction of movement of the AV 702 during navigation. Safety system 736 can include lights and signal indicators, a parking brake, airbags, and so forth. The cabin system 738 can include cabin temperature control systems, in-cabin entertainment systems, and so forth. In some embodiments, the AV 702 may not include human driver actuators (e.g., steering wheel, handbrake, foot brake pedal, foot accelerator pedal, turn signal lever, window wipers, etc.) for controlling the AV 702. Instead, the cabin system 738 can include one or more client interfaces (e.g., Graphical User Interfaces (GUIs), Voice User Interfaces (VUIs), etc.) for controlling certain aspects of the mechanical systems 730-738.

AV 702 can additionally include a local computing device 710 that is in communication with the sensor systems 704-708, the mechanical systems 730-738, the data center 750, and the client computing device 770, among other systems. The local computing device 710 can include one or more processors and memory, including instructions that can be executed by the one or more processors. The instructions can make up one or more software stacks or components responsible for controlling the AV 702; communicating with the data center 750, the client computing device 770, and other systems; receiving inputs from riders, passengers, and other entities within the AV's environment; logging metrics collected by the sensor systems 704-708; and so forth. In this example, the local computing device 710 includes a perception stack 712, a mapping and localization stack 714, a planning stack 716, a control stack 718, a communications stack 720, a High Definition (HD) geospatial database 722, and an AV operational database 724, among other stacks and systems.

Perception stack 712 can enable the AV 702 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 704-708, the mapping and localization stack 714, the HD geospatial database 722, other components of the AV, and other data sources (e.g., the data center 750, the client computing device 770, third-party data sources, etc.). The perception stack 712 can detect and classify objects and determine their current and predicted locations, speeds, directions, and the like. In addition, the perception stack 712 can determine the free space around the AV 702 (e.g., to maintain a safe distance from other objects, change lanes, park the AV, etc.). The perception stack 712 can also identify environmental uncertainties, such as where to look for moving objects, flag areas that may be obscured or blocked from view, and so forth.

Mapping and localization stack 714 can determine the AV's position and orientation (pose) using different methods from multiple systems (e.g., GPS, IMUs, cameras, LIDAR, RADAR, ultrasonic sensors, the HD geospatial database 722, etc.). For example, in some embodiments, the AV 702 can compare sensor data captured in real-time by the sensor systems 704-708 to data in the HD geospatial database 722 to determine its precise (e.g., accurate to the order of a few centimeters or less) position and orientation. The AV 702 can focus its search based on sensor data from one or more first sensor systems (e.g., GPS) by matching sensor data from one or more second sensor systems (e.g., LIDAR). If the mapping and localization information from one system is unavailable, the AV 702 can use mapping and localization information from a redundant system and/or from remote data sources.

The planning stack 716 can determine how to maneuver or operate the AV 702 safely and efficiently in its environment. For example, the planning stack 716 can receive the location, speed, and direction of the AV 702, geospatial data, data regarding objects sharing the road with the AV 702 (e.g., pedestrians, bicycles, vehicles, ambulances, buses, cable cars, trains, traffic lights, lanes, road markings, etc.) or certain events occurring during a trip (e.g., an Emergency Vehicle (EMV) blaring a siren, intersections, occluded areas, street closures for construction or street repairs, Double-Parked Vehicles (DPVs), etc.), traffic rules and other safety standards or practices for the road, user input, and other relevant data for directing the AV 702 from one point to another. The planning stack 716 can determine multiple sets of one or more mechanical operations that the AV 702 can perform (e.g., go straight at a specified speed or rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the one to meet changing road conditions and events. If something unexpected happens, the planning stack 716 can select from multiple backup plans to carry out. For example, while preparing to change lanes to turn right at an intersection, another vehicle may aggressively cut into the destination lane, making the lane change unsafe. The planning stack 716 could have already determined an alternative plan for such an event, and upon its occurrence, help to direct the AV 702 to go around the block instead of blocking a current lane while waiting for an opening to change lanes.

The control stack 718 can manage the operation of the vehicle propulsion system 730, the braking system 732, the steering system 734, the safety system 736, and the cabin system 738. The control stack 718 can receive sensor signals from the sensor systems 704-708 as well as communicate with other stacks or components of the local computing device 710 or a remote system (e.g., the data center 750) to effectuate operation of the AV 702. For example, the control stack 718 can implement the final path or actions from the multiple paths or actions provided by the planning stack 716. This can involve turning the routes and decisions from the planning stack 716 into commands for the actuators that control the AV's steering, throttle, brake, and drive unit.

The communication stack 720 can transmit and receive signals between the various stacks and other components of the AV 702 and between the AV 702, the data center 750, the client computing device 770, and other remote systems. The communication stack 720 can enable the local computing device 710 to exchange information remotely over a network, such as through an antenna array or interface that can provide a metropolitan WIFI® network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communication stack 720 can also facilitate local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 722 can store HD maps and related data of the streets upon which the AV 702 travels. In some embodiments, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane or road centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines, and/or boundaries, etc.) and related attributes (e.g., permissive, protected/permissive, or protected only left turn lanes; permissive, protected/permissive, or protected only U-turn lanes; permissive or protected only right turn lanes; etc.). The traffic controls layer can include geospatial information of traffic signal lights, traffic signs, and other road objects and related attributes.

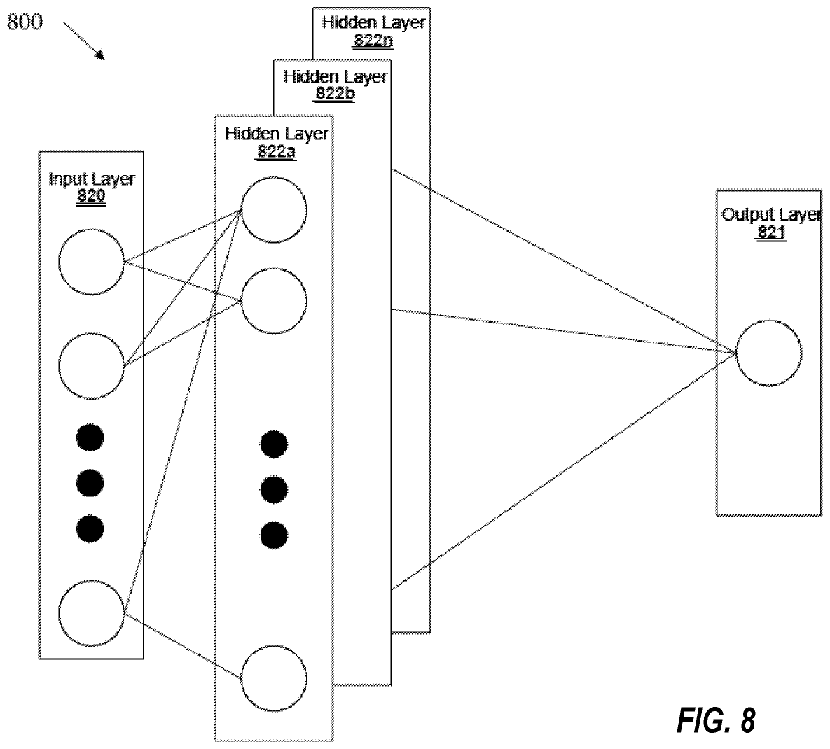

The AV operational database 724 can store raw AV data generated by the sensor systems 704-708 and other components of the AV 702 and/or data received by the AV 702 from remote systems (e.g., the data center 750, the client computing device 770, etc.). In some embodiments, the raw AV data can include HD LIDAR point cloud data, image or video data, RADAR data, GPS data, and other sensor data that the data center 750 can use for creating or updating AV geospatial data as discussed further below with respect to FIG. 8 and elsewhere in the present disclosure.

The data center 750 can be a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and so forth. The data center 750 can include one or more computing devices remote to the local computing device 710 for managing a fleet of AVs and AV-related services. For example, in addition to managing the AV 702, the data center 750 may also support a ridesharing service, a delivery service, a remote/roadside assistance service, street services (e.g., street mapping, street patrol, street cleaning, street metering, parking reservation, etc.), and the like.

The data center 750 can send and receive various signals to and from the AV 702 and the client computing device 770. These signals can include sensor data captured by the sensor systems 704-708, roadside assistance requests, software updates, ridesharing pick-up and drop-off instructions, and so forth. In this example, the data center 750 includes one or more of a data management platform 752, an Artificial Intelligence/Machine Learning (AI/ML) platform 754, a simulation platform 756, a remote assistance platform 758, a ridesharing platform 760, and a map management platform 762, among other systems.

Data management platform 752 can be a “big data” system capable of receiving and transmitting data at high speeds (e.g., near real-time or real-time), processing a large variety of data, and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service data, map data, audio data, video data, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 750 can access data stored by the data management platform 752 to provide their respective services.

The AI/ML platform 754 can provide the infrastructure for training and evaluating machine learning algorithms for operating the AV 702, the simulation platform 756, the remote assistance platform 758, the ridesharing platform 760, the map management platform 762, and other platforms and systems. Using the AI/ML platform 754, data scientists can prepare data sets from the data management platform 752; select, design, and train machine learning models; evaluate, refine, and deploy the models; maintain, monitor, and retrain the models; and so on.

The simulation platform 756 can enable testing and validation of the algorithms, machine learning models, neural networks, and other development efforts for the AV 702, the remote assistance platform 758, the ridesharing platform 760, the map management platform 762, and other platforms and systems. The simulation platform 756 can replicate a variety of driving environments and/or reproduce real-world scenarios from data captured by the AV 702, including rendering geospatial information and road infrastructure (e.g., streets, lanes, crosswalks, traffic lights, stop signs, etc.) obtained from the map management platform 762; modeling the behavior of other vehicles, bicycles, pedestrians, and other dynamic elements; simulating inclement weather conditions, different traffic scenarios; and so on.

The remote assistance platform 758 can generate and transmit instructions regarding the operation of the AV 702. For example, in response to an output of the AI/ML platform 754 or other system of the data center 750, the remote assistance platform 758 can prepare instructions for one or more stacks or other components of the AV 702.

The ridesharing platform 760 can interact with a customer of a ridesharing service via a ridesharing application 772 executing on the client computing device 770. The client computing device 770 can be any type of computing system, including a server, desktop computer, laptop, tablet, smartphone, smart wearable device (e.g., smart watch; smart eyeglasses or other Head-Mounted Display (HMD); smart ear pods or other smart in-car, on-ear, or over-ear device; etc.), gaming system, or other general purpose computing device for accessing the ridesharing application 772. The client computing device 770 can be a customer's mobile computing device or a computing device integrated with the AV 702 (e.g., the local computing device 710). The ridesharing platform 760 can receive requests to be picked up or dropped off from the ridesharing application 772 and dispatch the AV 702 for the trip.

Map management platform 762 can provide a set of tools for the manipulation and management of geographic and spatial (geospatial) and related attribute data. The data management platform 752 can receive LIDAR point cloud data, image data (e.g., still image, video, etc.), RADAR data, GPS data, and other sensor data (e.g., raw data) from one or more AVs 702, Unmanned Aerial Vehicles (UAVs), satellites, third-party mapping services, and other sources of geospatially referenced data. The raw data can be processed, and map management platform 762 can render base representations (e.g., tiles (2D), bounding volumes (3D), etc.) of the AV geospatial data to enable users to view, query, label, edit, and otherwise interact with the data. Map management platform 762 can manage workflows and tasks for operating on the AV geospatial data. Map management platform 762 can control access to the AV geospatial data, including granting or limiting access to the AV geospatial data based on user-based, role-based, group-based, task-based, and other attribute-based access control mechanisms. Map management platform 762 can provide version control for the AV geospatial data, such as to track specific changes that (human or machine) map editors have made to the data and to revert changes. Map management platform 762 can administer release management of the AV geospatial data, including distributing suitable iterations of the data to different users, computing devices, AVs, and other consumers of HD maps. Map management platform 762 can provide analytics regarding the AV geospatial data and related data, such as to generate insights relating to the throughput and quality of mapping tasks.

In some embodiments, the map viewing services of map management platform 762 can be modularized and deployed as part of one or more of the platforms and systems of the data center 750. For example, the AI/ML platform 754 may incorporate the map viewing services for visualizing the effectiveness of various object detection or object classification models, the simulation platform 756 may incorporate the map viewing services for recreating and visualizing certain driving scenarios, the remote assistance platform 758 may incorporate the map viewing services for replaying traffic incidents to facilitate and coordinate aid, the ridesharing platform 760 may incorporate the map viewing services into the client application 772 to enable passengers to view the AV 702 in transit en route to a pick-up or drop-off location, and so on.

In FIG. 8, the disclosure now turns to a further discussion of models that can be used through the environments and techniques described herein. Specifically, FIG. 8 is an illustrative example of a deep learning neural network 800 that can be used to implement all or a portion of a perception module (or perception system) as discussed above. An input layer 820 can be configured to receive sensor data and/or data relating to an environment surrounding an AV. The neural network 800 includes multiple hidden layers 822a, 822b, through 822n. The hidden layers 822a, 822b, through 822n include “n” number of hidden layers, where “n” is an integer greater than or equal to one. The number of hidden layers can be made to include as many layers utilized for the given application. The neural network 800 further includes an output layer 821 that provides an output resulting from the processing performed by the hidden layers 822a, 822b, through 822n. In one illustrative example, the output layer 821 can provide estimated treatment parameters that can be used/ingested by a differential simulator to estimate a patient treatment outcome.

The neural network 800 is a multi-layer neural network of interconnected nodes. Each node can represent a piece of information. Information associated with the nodes is shared among the different layers and each layer retains information as information is processed. In some cases, the neural network 800 can include a feed-forward network, in which case there are no feedback connections where outputs of the network are fed back into itself. In some cases, the neural network 800 can include a recurrent neural network, which can have loops that allow information to be carried across nodes while reading in input.

Information can be exchanged between nodes through node-to-node interconnections between the various layers. Nodes of the input layer 820 can activate a set of nodes in the first hidden layer 822a. For example, as shown, each of the input nodes of the input layer 820 is connected to each of the nodes of the first hidden layer 822a. The nodes of the first hidden layer 822a can transform the information of each input node by applying activation functions to the input node information. The information derived from the transformation can then be passed to and can activate the nodes of the next hidden layer 822b, which can perform their own designated functions. Example functions include convolutional, up-sampling, data transformation, and/or any other suitable functions. The output of the hidden layer 822b can then activate nodes of the next hidden layer, and so on. The output of the last hidden layer 822n can activate one or more nodes of the output layer 821, at which an output is provided. In some cases, while nodes in the neural network 800 are shown as having multiple output lines, a node can have a single output and all lines shown as being output from a node represent the same output value.

In some cases, each node or interconnection between nodes can have a weight that is a set of parameters derived from the training of the neural network 800. Once the neural network 800 is trained, it can be referred to as a trained neural network, which can be used to classify one or more activities. For example, an interconnection between nodes can represent a piece of information learned about the interconnected nodes. The interconnection can have a tunable numeric weight that can be tuned (e.g., based on a training dataset), allowing the neural network 800 to be adaptive to inputs and able to learn as more and more data is processed.

The neural network 800 is pre-trained to process the features from the data in the input layer 820 using the different hidden layers 822a, 822b, through 822n in order to provide the output through the output layer 821.

In some cases, the neural network 800 can adjust the weights of the nodes using a training process called backpropagation. A backpropagation process can include a forward pass, a loss function, a backward pass, and a weight update. The forward pass, loss function, backward pass, and parameter/weight update is performed for one training iteration. The process can be repeated for a certain number of iterations for each set of training data until the neural network 800 is trained well enough so that the weights of the layers are accurately tuned.

To perform training, a loss function can be used to analyze errors in the output. Any suitable loss function definition can be used, such as a Cross-Entropy loss. Another example of a loss function includes the mean squared error (MSE), defined as E_total=Σ(½(target−output)²). The loss can be set to be equal to the value of E_total.

The loss (or error) will be high for the initial training data since the actual values will be much different than the predicted output. The goal of training is to minimize the amount of loss so that the predicted output is the same as the training output. The neural network 800 can perform a backward pass by determining which inputs (weights) most contributed to the loss of the network, and can adjust the weights so that the loss decreases and is eventually minimized.

The neural network 800 can include any suitable deep network. One example includes a Convolutional Neural Network (CNN), which includes an input layer and an output layer, with multiple hidden layers between the input and out layers. The hidden layers of a CNN include a series of convolutional, nonlinear, pooling (for downsampling), and fully connected layers. The neural network 800 can include any other deep network other than a CNN, such as an autoencoder, Deep Belief Nets (DBNs), Recurrent Neural Networks (RNNs), among others.

As understood by those of skill in the art, machine-learning based classification techniques can vary depending on the desired implementation. For example, machine-learning classification schemes can utilize one or more of the following, alone or in combination: hidden Markov models; RNNs; CNNs; deep learning; Bayesian symbolic methods; Generative Adversarial Networks (GANs); support vector machines; image registration methods; and applicable rule-based systems. Where regression algorithms are used, they may include but are not limited to: a Stochastic Gradient Descent Regressor, a Passive Aggressive Regressor, etc.

Machine learning classification models can also be based on clustering algorithms (e.g., a Mini-batch K-means clustering algorithm), a recommendation algorithm (e.g., a Minwise Hashing algorithm, or Euclidean Locality-Sensitive Hashing (LSH) algorithm), and/or an anomaly detection algorithm, such as a local outlier factor. Additionally, machine-learning models can employ a dimensionality reduction approach, such as, one or more of: a Mini-batch Dictionary Learning algorithm, an incremental Principal Component Analysis (PCA) algorithm, a Latent Dirichlet Allocation algorithm, and/or a Mini-batch K-means algorithm, etc.

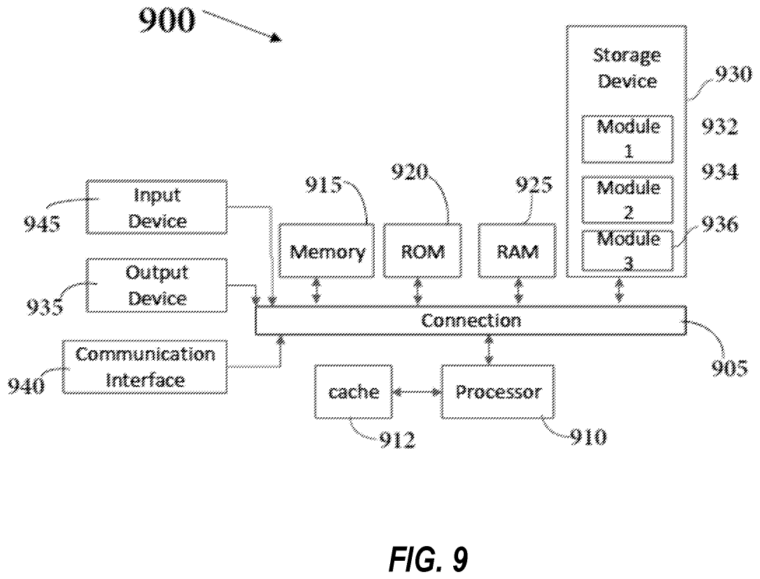

FIG. 9 illustrates an example processor-based system with which some aspects of the subject technology can be implemented. For example, processor-based system 900 can be any computing device making up, or any component thereof in which the components of the system are in communication with each other using connection 905. Connection 905 can be a physical connection via a bus, or a direct connection into processor 910, such as in a chipset architecture. Connection 905 can also be a virtual connection, networked connection, or logical connection.

In some embodiments, computing system 900 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 900 includes at least one processing unit (Central Processing Unit (CPU) or processor) 910 and connection 905 that couples various system components including system memory 915, such as Read-Only Memory (ROM) 920 and Random-Access Memory (RAM) 925 to processor 910. Computing system 900 can include a cache of high-speed memory 912 connected directly with, in close proximity to, or integrated as part of processor 910.

Processor 910 can include any general-purpose processor and a hardware service or software service, such as services 932, 934, and 936 stored in storage device 930, configured to control processor 910 as well as a special-purpose processor where software instructions are incorporated into the actual processor design. Processor 910 may be a completely self-contained computing system, containing multiple cores or processors, a bus, memory controller, cache, etc. A multi-core processor may be symmetric or asymmetric.

To enable user interaction, computing system 900 includes an input device 945, which can represent any number of input mechanisms, such as a microphone for speech, a touch-sensitive screen for gesture or graphical input, keyboard, mouse, motion input, speech, etc. Computing system 900 can also include output device 935, which can be one or more of a number of output mechanisms known to those of skill in the art. In some instances, multimodal systems can enable a user to provide multiple types of input/output to communicate with computing system 900. Computing system 900 can include communications interface 940, which can generally govern and manage the user input and system output. The communication interface may perform or facilitate receipt and/or transmission wired or wireless communications via wired and/or wireless transceivers, including those making use of an audio jack/plug, a microphone jack/plug, a Universal Serial Bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 802.11 Wi-Fi® wireless signal transfer, Wireless Local Area Network (WLAN) signal transfer, Visible Light Communication (VLC) signal transfer, Worldwide

Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communications interface 940 may also include one or more Global Navigation Satellite System (GNSS) receivers or transceivers that are used to determine a location of the computing system 900 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 930 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a Compact Disc (CD) Read Only Memory (CD-ROM) optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another Integrated Circuit (IC) chip/card, Random-Access Memory (RAM), Atatic RAM (SRAM), Dynamic RAM (DRAM), Read-Only Memory (ROM), Programmable ROM (PROM), Erasable PROM (EPROM), Electrically Erasable PROM (EEPROM), flash EPROM (FLASHEPROM), cache memory (L1/L2/L3/L4/L5/L#), Resistive RAM (RRAM/ReRAM), Phase Change Memory (PCM), Spin Transfer Torque RAM (STT-RAM), another memory chip or cartridge, and/or a combination thereof.

Storage device 930 can include software services, servers, services, etc., that when the code that defines such software is executed by the processor 910, it causes the system 900 to perform a function. In some embodiments, a hardware service that performs a particular function can include the software component stored in a computer-readable medium in connection with the hardware components, such as processor 910, connection 905, output device 935, etc., to carry out the function.

Embodiments within the scope of the disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions utilized in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network Personal Computers (PCs), minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

### SELECTED EXAMPLES

Example 1 includes a method for facilitating an integrated AV signal quality-based review recommendation system, where the method comprises receiving, by a processing device, performance results corresponding to tests performed using simulated mileage accumulation of at least one simulated autonomous vehicles (AV); filtering, by the processing device, the tests based on validity information of the tests, wherein the tests that are identified as invalid are discarded; filtering, by the processing device, the performance results of the tests identified as valid based on performance criteria to provide a set of selected tests; performing, by the processing device, a sensitivity analysis on the set of selected tests to determine a trustworthiness signal for each selected test in the set of selected tests; and ranking and recommending, by the processing device, one or more of the selected tests in the set of selected tests using a centralized ranking technique that considers the performance results and the trustworthiness signal of the selected tests.

In Example 2, the subject matter of Example 1 can optionally include wherein the performance results comprise at least one of miles per safety critical event (SCE), number of miles per SCE, number of SCE, miles per vehicle retrieval event (VRE), number of VREs, comfort scores, miles per remote assistance events, or number of remote assistance events. In Example 3, the subject matter of any one of Examples 1-2 can optionally include wherein the validity information comprises objective validity information and subjective validity information. In Example 4, the subject matter of any one of Examples 1-3 can optionally include wherein the objective validity information comprises at least on one of hot start issue or divergence issue, and wherein the subjective validity information comprises road participant realism.

In Example 5, the subject matter of any one of Examples 1-4 can optionally include further comprising grouping, by the processing device using unsupervised grouping techniques, the set of selected tests into signal groups based on scenario characteristics corresponding to the selected tests. In Example 6, the subject matter of any one of Examples 1-5 can optionally include wherein the ranking and the recommending of the one or more of the selected tests is performed for each signal group. In Example 7, the subject matter of any one of Examples 1-6 can optionally include wherein the signal groups comprise at least one of maneuvers of the at least one simulated AV or a type of road participant interacting with the at least one simulated AV.

In Example 8, the subject matter of any one of Examples 1-7 can optionally include wherein filtering the performance results of the valid tests based on the performance criteria further comprises: analyzing the performance results, static test inputs for the tests, and dynamic test inputs for the tests to identify any test validity issues with the tests; discarding the tests identified as invalid; and applying a performance filter to the tests identified as valid to identify the selected tests that satisfy determined performance qualifications, wherein the performance qualifications are configured. In Example 9, the subject matter of any one of Examples 1-8 can optionally include wherein the sensitivity analysis comprises: receiving historical test results corresponding to the set of the selected tests; perturbing an evaluation window for test runs of each of the set of selected tests; comparing, using the perturbed evaluation window, the tests runs of each selected test to determine a sensitivity to noise for each selected test; and assigning the trustworthiness signal to each selected test based on the determined sensitivity to noise.

Example 10 includes an apparatus for facilitating an integrated AV signal quality-based review recommendation system, the apparatus of Example 10 comprising one or more hardware processors to receive performance results corresponding to tests performed using simulated mileage accumulation of at least one simulated autonomous vehicles (AV); filter the tests based on validity information of the tests, wherein the tests that are identified as invalid are discarded; filter the performance results of the tests identified as valid based on performance criteria to provide a set of selected tests; perform a sensitivity analysis on the set of selected tests to determine a trustworthiness signal for each selected test in the set of selected tests; and rank and recommend one or more of the selected tests in the set of selected tests using a centralized ranking technique that considers the performance results and the trustworthiness signal of the selected tests.

In Example 11, the subject matter of Example 10 can optionally include wherein the validity information comprises objective validity information and subjective validity information, wherein the objective validity information comprises at least on one of hot start issue or divergence issue, and wherein the subjective validity information comprises road participant realism. In Example 12, the subject matter of Examples 10-11 can optionally include wherein the one or more processors are further to group, using unsupervised grouping techniques, the set of selected tests into signal groups based on scenario characteristics corresponding to the selected tests, wherein the ranking and the recommending of the one or more of the selected tests is performed for each signal group.

In Example 13, the subject matter of Examples 10-12 can optionally include wherein the signal groups comprise at least one of maneuvers of the at least one simulated AV or a type of road participant interacting with the at least one simulated AV. In Example 14, the subject matter of Examples 10-13 can optionally include wherein the one or more processors to filter the performance results of the valid tests based on the performance criteria further comprises the one or more processors to: analyze the performance results, static test inputs for the tests, and dynamic test inputs for the tests to identify any test validity issues with the tests; discard the tests identified as invalid; and apply a performance filter to the tests identified as valid to identify the selected tests that satisfy determined performance qualifications, wherein the performance qualifications are configured.

In Example 15, the subject matter of Examples 10-14 can optionally include wherein the sensitivity analysis comprises the one or more processors to: receive historical test results corresponding the set of the selected tests; perturb an evaluation window for test runs of each of the set of selected tests; compare, using the perturbed evaluation window, the tests runs of each selected test to determine a sensitivity to noise for each selected test; and assign the trustworthiness signal to each selected test based on the determined sensitivity to noise.

Example 16 is a non-transitory computer-readable storage medium for facilitating an integrated AV signal quality-based review recommendation system. The non-transitory computer-readable storage medium of Example 16 having stored thereon executable computer program instructions that, when executed by one or more processors, cause the one or more processors to: receive performance results corresponding to tests performed using simulated mileage accumulation of at least one simulated autonomous vehicles (AV); filter the tests based on validity information of the tests, wherein the tests that are identified as invalid are discarded; filter the performance results of the tests identified as valid based on performance criteria to provide a set of selected tests; perform a sensitivity analysis on the set of selected tests to determine a trustworthiness signal for each selected test in the set of selected tests; and rank and recommend one or more of the selected tests in the set of selected tests using a centralized ranking technique that considers the performance results and the trustworthiness signal of the selected tests.

In Example 17, the subject matter of Example 16 can optionally include wherein the validity information comprises objective validity information and subjective validity information, wherein the objective validity information comprises at least on one of hot start issue or divergence issue, and wherein the subjective validity information comprises road participant realism. In Example 18, the subject matter of Examples 16-17 can optionally include wherein the one or more processors are further to group, using unsupervised grouping techniques, the set of selected tests into signal groups based on scenario characteristics corresponding to the selected tests, wherein the ranking and the recommending of the one or more of the selected tests is performed for each signal group.

In Example 19, the subject matter of Examples 16-18 can optionally include wherein the one or more processors to filter the performance results of the valid tests based on the performance criteria further comprises the one or more processors to: analyze the performance results, static test inputs for the tests, and dynamic test inputs for the tests to identify any test validity issues with the tests; discard the tests identified as invalid; and apply a performance filter to the tests identified as valid to identify the selected tests that satisfy determined performance qualifications, wherein the performance qualifications are configured. In Example 20, the subject matter of Examples 16-19 can optionally include wherein the sensitivity analysis comprises the one or more processors to: receive historical test results corresponding to the set of the selected tests; perturb an evaluation window for test runs of each of the set of selected tests; compare, using the perturbed evaluation window, the tests runs of each selected test to determine a sensitivity to noise for each selected test; and assign the trustworthiness signal to each selected test based on the determined sensitivity to noise.

Example 21 is a system for facilitating an integrated AV signal quality-based review recommendation system. The system of Example 21 can optionally include a memory to store a block of data, and one or more hardware processors to receive performance results corresponding to tests performed using simulated mileage accumulation of at least one simulated autonomous vehicles (AV); filter the tests based on validity information of the tests, wherein the tests that are identified as invalid are discarded; filter the performance results of the tests identified as valid based on performance criteria to provide a set of selected tests; perform a sensitivity analysis on the set of selected tests to determine a trustworthiness signal for each selected test in the set of selected tests; and rank and recommend one or more of the selected tests in the set of selected tests using a centralized ranking technique that considers the performance results and the trustworthiness signal of the selected tests.

In Example 22, the subject matter of Example 21 can optionally include wherein the validity information comprises objective validity information and subjective validity information, wherein the objective validity information comprises at least on one of hot start issue or divergence issue, and wherein the subjective validity information comprises road participant realism. In Example 23, the subject matter of Examples 21-22 can optionally include wherein the one or more processors are further to group, using unsupervised grouping techniques, the set of selected tests into signal groups based on scenario characteristics corresponding to the selected tests, wherein the ranking and the recommending of the one or more of the selected tests is performed for each signal group.

In Example 24, the subject matter of Examples 21-23 can optionally include wherein the signal groups comprise at least one of maneuvers of the at least one simulated AV or a type of road participant interacting with the at least one simulated AV. In Example 25, the subject matter of Examples 21-24 can optionally include wherein the one or more processors to filter the performance results of the valid tests based on the performance criteria further comprises the one or more processors to: analyze the performance results, static test inputs for the tests, and dynamic test inputs for the tests to identify any test validity issues with the tests; discard the tests identified as invalid; and apply a performance filter to the tests identified as valid to identify the selected tests that satisfy determined performance qualifications, wherein the performance qualifications are configured.

In Example 26, the subject matter of Examples 21-25 can optionally include wherein the sensitivity analysis comprises the one or more processors to: receive historical test results corresponding to the set of the selected tests; perturb an evaluation window for test runs of each of the set of selected tests; compare, using the perturbed evaluation window, the tests runs of each selected test to determine a sensitivity to noise for each selected test; and assign the trustworthiness signal to each selected test based on the determined sensitivity to noise.

Example 27 includes an apparatus comprising means for performing the method of any of the Examples 1-9. Example 28 is at least one machine readable medium comprising a plurality of instructions that in response to being executed on a computing device, cause the computing device to carry out a method according to any one of Examples 1-9. Example 29 is an apparatus for facilitating an integrated AV signal quality-based review recommendation system, configured to perform the method of any one of Examples 1-9. Specifics in the Examples may be used anywhere in one or more embodiments.

The various embodiments described above are provided by way of illustration and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure. Claim language reciting “at least one of” a set indicates that one member of the set or multiple members of the set satisfy the claim.

What is claimed is:

1. A method comprising:
receiving, by a processing device, performance results corresponding to tests performed using simulated mileage accumulation of at least one simulated autonomous vehicles (AV);
filtering, by the processing device, the tests based on validity information of the tests, wherein the tests that are identified as invalid are discarded;
filtering, by the processing device, the performance results of the tests identified as valid based on performance criteria to provide a set of selected tests;
performing, by the processing device, a sensitivity analysis on the set of selected tests to determine a trustworthiness signal for each selected test in the set of selected tests; and
ranking and recommending, by the processing device, one or more of the selected tests in the set of selected tests using a centralized ranking technique that considers the performance results and the trustworthiness signal of the selected tests.

2. The method of claim 1, wherein the performance results comprise at least one of miles per safety critical event (SCE), number of SCEs, miles per vehicle retrieval event (VRE), number of VREs, comfort scores, miles per remote assistance events, or number of remote assistance events.

3. The method of claim 1, wherein the validity information comprises objective validity information and subjective validity information.

4. The method of claim 3, wherein the objective validity information comprises at least one of hot start issue or divergence issue, and wherein the subjective validity information comprises road participant realism.

5. The method of claim 1, further comprising grouping, by the processing device using unsupervised grouping techniques, the set of selected tests into signal groups based on scenario characteristics corresponding to the selected tests.

6. The method of claim 5, wherein the ranking and the recommending of the one or more of the selected tests is performed for each signal group.

7. The method of claim 5, wherein the signal groups comprise at least one of maneuvers of the at least one simulated AV or a type of road participant interacting with the at least one simulated AV.

8. The method of claim 1, wherein filtering the performance results of the valid tests based on the performance criteria further comprises:
analyzing the performance results, static test inputs for the tests, and dynamic test inputs for the tests to identify any test validity issues with the tests;
discarding the tests identified as invalid; and
applying a performance filter to the tests identified as valid to identify the selected tests that satisfy determined performance qualifications, wherein the performance qualifications are configured.

9. The method of claim 1, wherein the sensitivity analysis comprises:
receiving historical test results corresponding to the set of the selected tests;
perturbing an evaluation window for test runs of each of the set of selected tests;
comparing, using the perturbed evaluation window, the tests runs of each selected test to determine a sensitivity to noise for each selected test; and
assigning the trustworthiness signal to each selected test based on the determined sensitivity to noise.

10. An apparatus comprising:
one or more hardware processors to:
receive performance results corresponding to tests performed using simulated mileage accumulation of at least one simulated autonomous vehicles (AV);
filter the tests based on validity information of the tests, wherein the tests that are identified as invalid are discarded;
filter the performance results of the tests identified as valid based on performance criteria to provide a set of selected tests;
perform a sensitivity analysis on the set of selected tests to determine a trustworthiness signal for each selected test in the set of selected tests; and
rank and recommend one or more of the selected tests in the set of selected tests using a centralized ranking technique that considers the performance results and the trustworthiness signal of the selected tests.

11. The apparatus of claim 10, wherein the validity information comprises objective validity information and subjective validity information, wherein the objective validity information comprises at least on one of hot start issue or divergence issue, and wherein the subjective validity information comprises road participant realism.

12. The apparatus of claim 10, wherein the one or more processors are further to group, using unsupervised grouping techniques, the set of selected tests into signal groups based on scenario characteristics corresponding to the selected tests, wherein the ranking and the recommending of the one or more of the selected tests is performed for each signal group.

13. The apparatus of claim 12, wherein the signal groups comprise at least one of maneuvers of the at least one simulated AV or a type of road participant interacting with the at least one simulated AV.

14. The apparatus of claim 10, wherein the one or more processors to filter the performance results of the valid tests based on the performance criteria further comprises the one or more processors to:
analyze the performance results, static test inputs for the tests, and dynamic test inputs for the tests to identify any test validity issues with the tests;
discard the tests identified as invalid; and
apply a performance filter to the tests identified as valid to identify the selected tests that satisfy determined performance qualifications, wherein the performance qualifications are configured.

15. The apparatus of claim 10, wherein the sensitivity analysis comprises the one or more processors to:
receive historical test results corresponding to the set of the selected tests;
perturb an evaluation window for test runs of each of the set of selected tests;
compare, using the perturbed evaluation window, the tests runs of each selected test to determine a sensitivity to noise for each selected test; and
assign the trustworthiness signal to each selected test based on the determined sensitivity to noise.

16. A non-transitory computer-readable medium having stored thereon instructions that, when executed by one or more processors, cause the one or more processors to:
receive performance results corresponding to tests performed using simulated mileage accumulation of at least one simulated autonomous vehicles (AV);
filter the tests based on validity information of the tests, wherein the tests that are identified as invalid are discarded;
filter the performance results of the tests identified as valid based on performance criteria to provide a set of selected tests;
perform a sensitivity analysis on the set of selected tests to determine a trustworthiness signal for each selected test in the set of selected tests; and
rank and recommend one or more of the selected tests in the set of selected tests using a centralized ranking technique that considers the performance results and the trustworthiness signal of the selected tests.

17. The non-transitory computer-readable medium of claim 16, wherein the validity information comprises objective validity information and subjective validity information, wherein the objective validity information comprises at least on one of hot start issue or divergence issue, and wherein the subjective validity information comprises road participant realism.

18. The non-transitory computer-readable medium of claim 16, wherein the one or more processors are further to group, using unsupervised grouping techniques, the set of selected tests into signal groups based on scenario characteristics corresponding to the selected tests, wherein the ranking and the recommending of the one or more of the selected tests is performed for each signal group.

19. The non-transitory computer-readable medium of claim 16, wherein the one or more processors to filter the performance results of the valid tests based on the performance criteria further comprises the one or more processors to:
analyze the performance results, static test inputs for the tests, and dynamic test inputs for the tests to identify any test validity issues with the tests;
discard the tests identified as invalid; and
apply a performance filter to the tests identified as valid to identify the selected tests that satisfy determined performance qualifications, wherein the performance qualifications are configured.

20. The non-transitory computer-readable medium of claim 16, wherein the sensitivity analysis comprises the one or more processors to:
receive historical test results corresponding to the set of the selected tests;
perturb an evaluation window for test runs of each of the set of selected tests;
compare, using the perturbed evaluation window, the tests runs of each selected test to determine a sensitivity to noise for each selected test; and
assign the trustworthiness signal to each selected test based on the determined sensitivity to noise.
